(19) United States
(12) Patent Application Publication
(10) Pub. No.: US 2024/0258180 A1
(43) Pub. Date: Aug. 1, 2024

(54) SEMICONDUCTOR DEVICE INCLUDING CRACK DETECTION CIRCUIT

(71) Applicant: SAMSUNG ELECTRONICS CO., LTD., Suwon-si (KR)

(72) Inventors: Taehong Kwon, Suwon-si (KR); Daeseok Byeon, Suwon-si (KR)

(73) Assignee: SAMSUNG ELECTRONICS CO., LTD., Suwon-si (KR)

(21) Appl. No.: 18/518,114

(22) Filed: Nov. 22, 2023

(30) Foreign Application Priority Data
Feb. 1, 2023 (KR) 10-2023-0013588

(51) Int. Cl. H01L 21/66; H01L 23/00; H01L 23/48; H01L 23/528; H01L 25/065; H10B 80/00

(52) U.S. Cl. CPC H01L 22/30; H01L 23/481; H01L 23/528; H01L 24/08; H01L 25/0657; H10B 80/00; H01L 2224/08145

(57) ABSTRACT

A semiconductor device includes a first semiconductor chip; a second semiconductor chip stacked on the first semiconductor chip, wherein a type of the second semiconductor chip is different from a type of the first semiconductor chip; and a crack detection circuit including: a first crack detection line repeatedly passing through an interface between the first semiconductor chip and the second semiconductor chip; a second crack detection line including a bonding pad or a through-via structure contacting a surface of the second semiconductor chip opposite to the interface; and a crack detector in the second semiconductor chip, the crack detector being configured to output a first test signal to the first crack detection line, receive a first reception signal from the first crack detection line, output a second test signal to the second crack detection line, and receive a second reception signal from the second crack detection line.

### CROSS-REFERENCE TO RELATED APPLICATION

This application is based on and claims priority under 35 U.S.C. § 119 to Korean Patent Application No. 10-2023-0013588, filed on Feb. 1, 2023, in the Korean Intellectual Property Office, the disclosure of which is incorporated by reference herein in its entirety.

### BACKGROUND

The present disclosure relates to a semiconductor device, and more particularly, to a semiconductor device including a crack detection circuit and including a plurality of layers.

Generally, integrated circuits are formed in a repeating pattern on a wafer of semiconductor material. The wafer is cut into a large number of individual semiconductor dies, and each of the cut semiconductor dies is packaged into semiconductor chips. Cracks may occur in the semiconductor die during the cutting and packaging process. It is required to precisely detect such cracks in order to prevent shipment of defective products. In addition, since various semiconductor packages capable of mounting a plurality of semiconductor chips are being researched, it is required to detect cracks generated in a plurality of semiconductor chips.

### SUMMARY

Example embodiments provide a semiconductor device including a crack detection circuit for detecting a crack.

According to an aspect of an example embodiment, a semiconductor device includes: a first semiconductor chip; a second semiconductor chip stacked on the first semiconductor chip, wherein a type of the second semiconductor chip is different from a type of the first semiconductor chip; and a crack detection circuit including: a first crack detection line repeatedly passing through an interface between the first semiconductor chip and the second semiconductor chip; a second crack detection line including a bonding pad or a through-via structure contacting a surface of the second semiconductor chip opposite to the interface; and a crack detector in the second semiconductor chip, the crack detector being configured to output a first test signal to the first crack detection line, receive a first reception signal from the first crack detection line, output a second test signal to the second crack detection line, and receive a second reception signal from the second crack detection line.

According to an aspect of an example embodiment, a semiconductor device includes: a first semiconductor chip including a memory cell array; a second semiconductor chip provided under the first semiconductor chip and including a peripheral circuit; and a crack detection circuit including: a first crack detection line repeatedly passing through an interface between the first semiconductor chip and the second semiconductor chip; a second crack detection line including a bonding pad contacting a surface of the first semiconductor chip opposite to the interface; and a crack detector in the second semiconductor chip, the crack detector being configured to output a first test signal to the first crack detection line, receive a first reception signal from the first crack detection line, output a second test signal to the second crack detection line, and receive a second reception signal from the second crack detection line.

According to an aspect of an example embodiment, a semiconductor device includes: a first semiconductor chip; a second semiconductor chip, each of the first semiconductor chip and the second semiconductor chip includes a memory cell array; a third semiconductor chip stacked under the second semiconductor chip and including a peripheral circuit; and a crack detection circuit including: a first crack detection line that repeatedly passes through an interface between the first semiconductor chip and the second semiconductor chip; a second crack detection line that repeatedly passes through an interface between the second semiconductor chip and the third semiconductor chip; and a crack detector in the third semiconductor chip, the crack detector being configured to output a first test signal to the first crack detection line, receive a first reception signal from the first crack detection line, output a second test signal to the second crack detection line, and receive a second reception signal from the second crack detection line.

### BRIEF DESCRIPTION OF THE DRAWINGS

The above and/or other aspects will be more clearly understood from the following detailed description of example embodiments taken in conjunction with the accompanying drawings, in which:

FIG. 1 is a perspective view illustrating a semiconductor device according to an embodiment;

FIG. 2 is an enlarged view of portion A of FIG. 1 for explaining a bonding pad;

FIG. 3 is a plan view of a first semiconductor chip of a semiconductor device according to an embodiment;

FIGS. 4A, 4B, and 4C are perspective views illustrating a semiconductor device according to an embodiment;

FIG. 5 is a circuit diagram illustrating a crack detection circuit included in a semiconductor device according to an embodiment;

FIG. 6 is a circuit diagram for explaining configurations of first inverter circuits of FIG. 5;

FIG. 7A is a timing diagram for describing a reception signal in a normal state in which no crack is generated in a semiconductor device according to an embodiment;

FIG. 7B is a timing diagram for describing a reception signal in a bad state in which a crack occurs in a semiconductor device according to an embodiment;

FIG. 8 is a perspective view illustrating a semiconductor device according to an embodiment;

FIGS. 9A and 9B are perspective views illustrating a semiconductor device according to an embodiment;

FIG. 10 is a block diagram illustrating a memory device according to an embodiment;

FIG. 11 is a plan view of a first semiconductor chip of the semiconductor device 110 according to an embodiment; and

FIG. 12 is a cross-sectional view of a memory device having a bonding vertical NAND (B-VNAND) structure, according to an embodiment.

### DETAILED DESCRIPTION

Hereinafter, example embodiments will be described in detail with reference to the accompanying drawings.

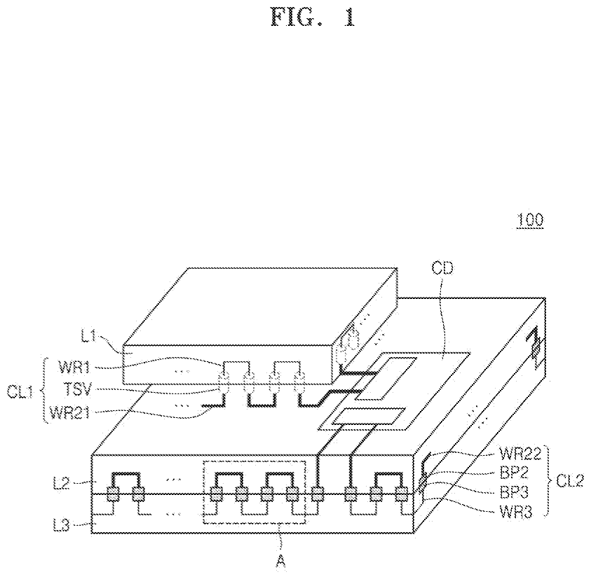

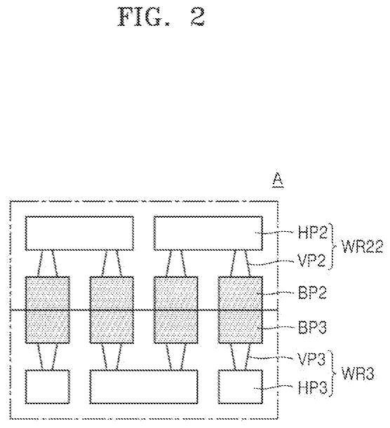

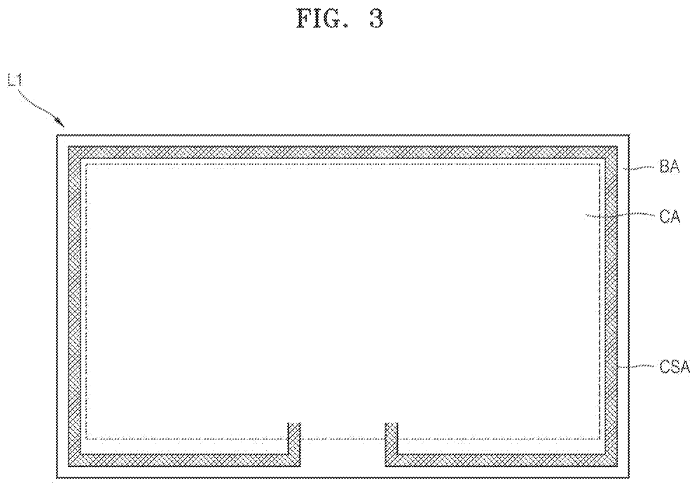

FIG. 1 is a perspective view illustrating a semiconductor device 100 according to an embodiment. FIG. 2 is an enlarged view of portion A of FIG. 1 for explaining a bonding pad. FIG. 3 is a plan view of a first semiconductor chip L1 of the semiconductor device 100 according to an embodiment.

The semiconductor device 100 according to an embodiment may be included in an electronic device. For example, the electronic device may include a smartphone, a tablet personal computer (PC), a portable multimedia player (PMP), a camera, a wearable device, a television, a digital video disk (DVD) player, a refrigerator, an air conditioner, an air purifier, a set-top box, a robot, a drone, various medical devices, a navigation device, a global positioning system receiver (GPS), an Advanced Drivers Assistance System (ADAS), a vehicle device, furniture, or various measuring devices. However, embodiments of the disclosure are not limited thereto, and the electronic device may be any other electronic device that processes data.

Referring to FIG. 1, the semiconductor device 100 may include a plurality of stacked semiconductor chips, for example, first, second, and third semiconductor chips L1, L2, and L3. Although semiconductor device 100 shown in FIG. 1 includes three stacked semiconductor chips, embodiments of the disclosure are not limited thereto, and the semiconductor device 100 may further include a semiconductor chip additionally stacked on the first semiconductor chip L1 or another semiconductor chip additionally stacked under the third semiconductor chip L3.

In an embodiment, the first, second, and third semiconductor chips L1, L2, and L3 may be heterogeneous semiconductor chips different from each other. Logic circuits may be formed in each of the first, second, and third semiconductor chips L1, L2, and L3 and may include semiconductor elements constituting the logic circuits. The semiconductor device 100 may have a chiplet structure.

In an embodiment, the first, second, and third semiconductor chips L1, L2, and L3 may be asymmetrically stacked. The size of at least one of the first, second, and third semiconductor chips L1, L2, and L3 may be different from that of other semiconductor chips, and for example, the size of the first semiconductor chip L1 may be smaller than that of the second semiconductor chip L2 and the third semiconductor chip L3. In this case, the size of a semiconductor chip may mean an area in the horizontal direction. Also, for example, the size of the second semiconductor chip L2 may be larger than that of the first semiconductor chip L1 and the third semiconductor chip L3.

Each of the first, second, and third semiconductor chips L1, L2, and L3 may include a substrate and an active layer formed on the substrate. Circuits may be formed on the active layer, and for example, the active layer may include a plurality of semiconductor elements and may include wiring layers on the semiconductor elements.

The substrate may include, for example, silicon (Si). Alternatively, each of the first substrate SUB1 and the second substrate SUB2 may include a semiconductor element, such as germanium (Ge), or a compound semiconductor such as silicon carbide (SiC), gallium arsenide (GaAs), indium arsenide (InAs), and indium phosphide (InP).

Semiconductor elements formed on the active layer may include microelectronic devices, such as a metal-oxide-semiconductor field effect transistor (MOSFET), a system large scale integration (LSI), an image sensor, such as a CMOS imaging sensor (CIS), a micro-electro-mechanical system (MEMS), an active element, a passive element, and the like.

In an embodiment, the first semiconductor chip L1 and the second semiconductor chip L2 may be electrically connected to each other through a through via structure TSV, and the second semiconductor chip L2 and the third semiconductor chip L3 may be electrically connected to each other through bonding pads BP2 and BP3. For example, the second semiconductor chip L2 and the third semiconductor chip L3 may be disposed face to face with active layers facing each other, and the active layer of the first semiconductor chip L1 and the active layer of the second semiconductor chip L2 may be disposed facing away from each other.

For example, the bonding pads BP2 and BP3 may be formed of copper (Cu), and this bonding method may be a Cu—Cu bonding method. As another example, the bonding pads BP2 and BP3 may also be formed of aluminum (Al) or tungsten (W).

The semiconductor device 100 may include a crack detection circuit that detects cracks generated in the first, second, and third semiconductor chips L1, L2, and L3. The crack detection circuit may include a crack detector CD, and a first crack detection line CL1 and a second crack detection line CL2 electrically connected to the crack detector CD.

The first crack detection line CL1 and the second crack detection line CL2 may be physically separated from each other and connected in parallel to each other within the crack detector CD. The crack detector CD may transmit a test signal to the first crack detection line CL1 and transmit a test signal to the second crack detection line CL2. Since the crack detector CD may transmit a test signal to each of the first crack detection line CL1 and the second crack detection line CL2, the semiconductor device 100 may detect a crack detection line in which a crack has occurred from a reception signal received from each of the first crack detection line CL1 and the second crack detection line CL2. That is, the semiconductor device 100 may detect a location where a crack is generated among the first, second, and third semiconductor chips L1, L2, and L3.

In an embodiment, the crack detector CD may be formed in the second semiconductor chip L2 disposed in the middle of the first, second, and third semiconductor chips L1, L2, and L3, but embodiments of the disclosure are not limited thereto. Test signals output from the crack detector CD to the first crack detection line CL1 and the second crack detection line CL2 may be pulses having a constant period and a constant width.

The first crack detection line CL1 may be formed to repeatedly cross the interface (boundary surface) between the first semiconductor chip L1 and the second semiconductor chip L2, and the second crack detection line CL2 may be formed to repeatedly cross the interface (boundary surface) between the second semiconductor chip L2 and the third semiconductor chip L3. For example, the first crack detection line CL1 may be formed in a zigzag shape at the interface between the first semiconductor chip L1 and the second semiconductor chip L2, and the second crack detection line CL2 may be formed in a zigzag shape at an interface between the second semiconductor chip L2 and the third semiconductor chip L3.

The first crack detection line CL1 may be formed to pass through the interface between the first semiconductor chip L1 and the second semiconductor chip L2 and may include a first wiring pattern WR1 formed on the first semiconductor chip L1, a second wiring pattern WR21 formed on the second semiconductor chip L2, and a through via structure TSV connecting the first and second wiring patterns WR1 and WR21 to each other. The through-via structure TSV may be formed to penetrate a portion of the second semiconductor chip L2, and for example, the through via structure TSV may penetrate a portion of the second semiconductor chip L2 and be electrically connected to an active surface of the second semiconductor chip L2.

In an embodiment, the first semiconductor chip L1 may include a pad that contacts the through-via structure TSV and is included in the first wiring pattern WR1. Alternatively, in an embodiment, the first semiconductor chip L1 may include a through via structure formed to contact the through via structure TSV and pass through a portion of the first semiconductor chip L1.

Referring to FIGS. 1 and 2, the second crack detection line CL2 may be formed to pass through the interface between the second semiconductor chip L2 and the third semiconductor chip L3 and may include a second wiring pattern WR22 and a bonding pad BP2 formed on the second semiconductor chip L2, and a third wiring pattern WR3 and a bonding pad BP3 formed on the third semiconductor chip L3. The bonding pad BP2 of the second semiconductor chip L2 and the bonding pad BP3 of the third semiconductor chip L3 are attached so that the second wiring pattern WR22 and the third wiring pattern WR3 are electrically connected to each other.

The second wiring pattern WR22 may include a horizontal pattern HP2 formed on a certain metal layer of the second semiconductor chip L2 and a vertical pattern VP2 connecting the horizontal pattern HP2 to the bonding pad BP2. At this time, in FIG. 2, the second wiring pattern WR22 includes only the horizontal pattern HP2 formed on one metal layer, but the second wiring pattern WR22 according to embodiments of the disclosure is not limited thereto, and the second wiring pattern WR22 may include horizontal patterns formed on each of the plurality of metal layers of the second semiconductor chip L2 and may further include vertical patterns connecting the horizontal patterns formed on different metal layers.

The third wiring pattern WR3 may include a horizontal pattern HP3 formed on a certain metal layer of the third semiconductor chip L3 and a vertical pattern VP3 connecting the horizontal pattern HP3 to the bonding pad BP3. At this time, in FIG. 2, the third wiring pattern WR3 includes only the horizontal pattern HP3 formed on one metal layer, but the third wiring pattern WR3 according to embodiments of the disclosure is not limited thereto, and the third wiring pattern WR3 includes horizontal patterns respectively formed on the plurality of metal layers of the third semiconductor chip L3 and may further include vertical patterns connecting the horizontal patterns formed on different metal layers.

Referring to FIGS. 1 and 3, the first semiconductor chip L1 may include a central area CA in which circuits including semiconductor elements are disposed and a boundary area BA formed to surround the central area CA. A crack detection area CSA in which the first crack detection line CL1 is disposed may be formed in the boundary area BA. Although the first semiconductor chip L1 is described as an example in FIG. 3, the description of the first semiconductor chip L1 described in FIG. 3 may also be applied to the second semiconductor chip L2 or the third semiconductor chip L3. That is, the first crack detection line CL1 and the second crack detection line CL2 formed in the second semiconductor chip L2 and the third semiconductor chip L3, respectively, may be formed in a boundary area formed to surround a central area where semiconductor elements are formed in each of the second semiconductor chip L2 and the third semiconductor chip L3.

Accordingly, the semiconductor device 100 according to one or more embodiments of the disclosure includes a plurality of stacked semiconductor chips L1, L2, and L3 and includes a first crack detection line CL1 and a second crack detection line CL2 formed to pass through interfaces between the plurality of semiconductor chips L1, L2, and L3 to detect a crack generated in the plurality of semiconductor chips L1, L2, and L3 so that it is possible to determine whether a crack has occurred in the semiconductor device 100 and to simultaneously detect a location of a semiconductor chip where a crack has occurred.

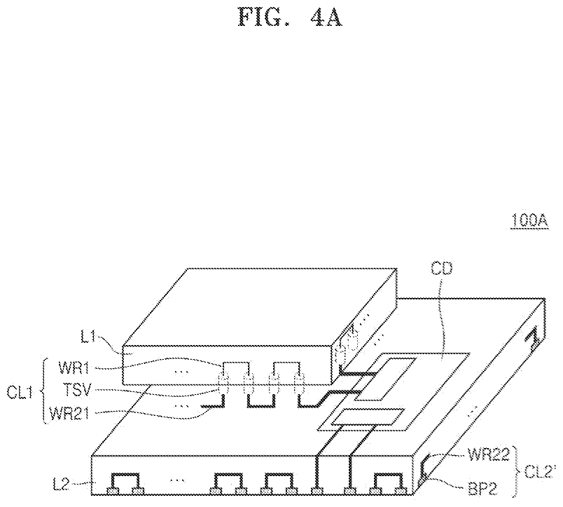

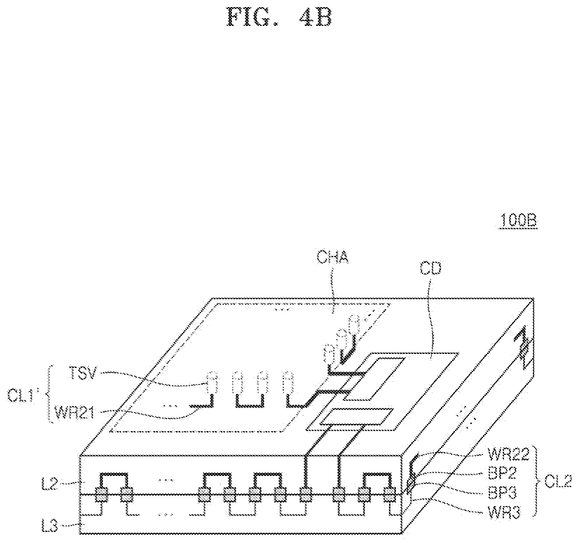

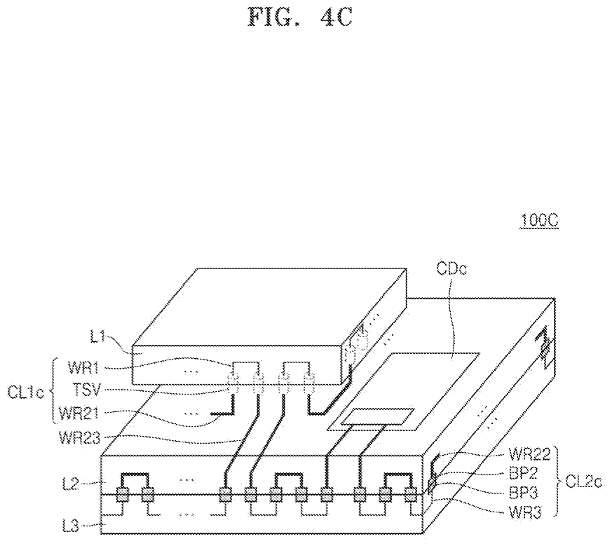

FIGS. 4A, 4B, and 4C are perspective views illustrating semiconductor devices 100A, 100B, and 100C according to example embodiments. In FIGS. 4A, 4B, and 4C, repeated descriptions of the same reference numerals as in FIG. 1 are be omitted.

Referring to FIG. 4A, the semiconductor device 100A may include a plurality of stacked semiconductor chips, for example, a first semiconductor chip L1 and a second semiconductor chip L2. The semiconductor device 100A may be connected to another semiconductor device attached to a lower portion of the second semiconductor chip L2.

The semiconductor device 100A may include a crack detection circuit that detects cracks generated in the first semiconductor chip L1 and the second semiconductor chip L2. The crack detection circuit may include a crack detector CD, and a first crack detection line CL1 and a second crack detection line CL2′ electrically connected to the crack detector CD.

At this time, the second crack detection line CL2′ may be formed on the second semiconductor chip L2 to contact the lower surface of the second semiconductor chip L2 and may include a second wiring pattern WR22 and a bonding pad BP2 formed on the second semiconductor chip L2. That is, the second crack detection line CL2′ may be formed to contact the lower surface of the second semiconductor chip L2 opposite to the interface between the first semiconductor chip L1 and the second semiconductor chip L2. The second crack detection line CL2′ may be electrically connected to wiring patterns of other semiconductor devices to be connected under the second semiconductor chip L2. After connecting another semiconductor device to the bottom of the semiconductor device 100A, the crack detection circuit of the semiconductor device 100A may transmit a test signal to the second crack detection line CL2′ and receive a reception signal from the second crack detection line CL2′, and the semiconductor device 100A may detect a crack generated in the second crack detection line CL2′, that is, a crack generated at an interface between the second semiconductor chip L2 and another semiconductor device.

Referring to FIG. 4B, the semiconductor device 100B may include a plurality of stacked semiconductor chips, for example, a second semiconductor chip L2 and a third semiconductor chip L3. In the semiconductor device 100B, another semiconductor device may be attached to and connected to the chip area CHA on the upper portion of the second semiconductor chip L2.

The semiconductor device 100B may include a crack detection circuit that detects cracks generated in the second semiconductor chip L2 and the third semiconductor chip L3. The crack detection circuit may include a crack detector CD, and a first crack detection line CL1′ and a second crack detection line CL2 electrically connected to the crack detector CD.

In this case, the first crack detection line CL1′ may be formed on the second semiconductor chip L2 to contact the top surface of the second semiconductor chip L2 and may include a second wiring pattern WR21 formed on the second semiconductor chip L2 and a through via structure TSV. That is, the first crack detection line CL1′ may be formed to contact the upper surface of the second semiconductor chip L2 opposite to the interface of the second semiconductor chip L2 and the third semiconductor chip L3.

The first crack detection line CL1′ may be electrically connected to a wiring pattern (e.g., a pad) of another semiconductor device to be connected to an upper portion of the second semiconductor chip L2. That is, the first crack detection line CL1′ may be formed in the chip area CHA, which is an area where another semiconductor device is to be disposed.

After connecting another semiconductor device to the top of the semiconductor device 100B, the crack detection circuit of the semiconductor device 100B may transmit a test signal to the first crack detection line CL1′ and receive a reception signal from the first crack detection line CL1′, and the semiconductor device 100B may detect a crack generated in the first crack detection line CL1′.

Referring to FIG. 4C, the semiconductor device 100C may include a plurality of stacked semiconductor chips, for example, first, second, and third semiconductor chips L1, L2, and L3. The semiconductor device 100C may include a crack detection circuit for detecting cracks generated in the first, second, and third semiconductor chips L1, L2, and L3, and the crack detection circuit may include a crack detector CDc, a first crack detection line CL1c, and a second crack detection line CL2c.

The first crack detection line CL1c may be formed to pass through the interface between the first semiconductor chip L1 and the second semiconductor chip L2 and may include a first wiring pattern WR1 formed on the first semiconductor chip L1, a second wiring pattern WR21 formed on the second semiconductor chip L2, and a through via structure TSV connecting the first and second wiring patterns WR1 and WR21 to each other. The second crack detection line CL2c may be formed to pass through the interface between the second semiconductor chip L2 and the third semiconductor chip L3 and may include a second wiring pattern WR22 and a bonding pad BP2 formed on the second semiconductor chip L2, and a third wiring pattern WR3 and a bonding pad BP3 formed on the third semiconductor chip L3.

The first crack detection line CL1c and the second crack detection line CL2c may be serially connected to each other. That is, the test signal output from the crack detector CDc may pass through both the first crack detection line CL1c and the second crack detection line CL2c and then be input to the crack detector CDc again as a reception signal. In an embodiment, the first crack detection line CL1c and the second crack detection line CL2c may be physically and electrically connected to each other through the second wiring pattern WR23 formed in the second semiconductor chip L2. The second wiring pattern WR23 may include a horizontal pattern formed on a certain metal layer of the second semiconductor chip L2 and a vertical pattern formed perpendicular to the horizontal pattern.

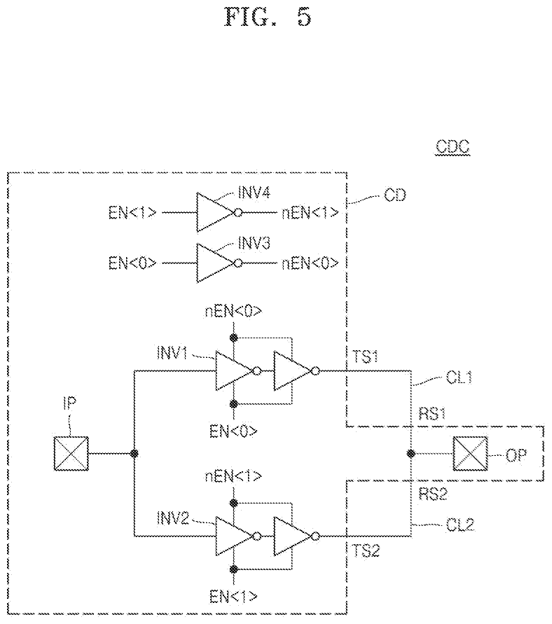

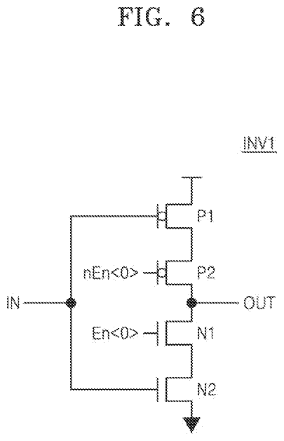

FIG. 5 is a circuit diagram illustrating a crack detection circuit CDC included in a semiconductor device according to an embodiment. FIG. 6 is a circuit diagram for explaining configurations of first inverter circuits of FIG. 5. The circuit diagram of FIG. 5 shows an embodiment in which the first crack detection line CL1 and the second crack detection line CL2 are connected in parallel to each other.

Referring to FIG. 5, the crack detection circuit CDC may include a crack detector CD, a first crack detection line CL1, and a second crack detection line CL2. The crack detector CD may transmit the first test signal TS1 through the first crack detection line CL1 and receive the first reception signal RS1 from the first crack detection line CL1. The crack detector CD may transmit the second test signal TS2 through the second crack detection line CL2 and receive the second reception signal RS2 from the second crack detection line CL2.

The crack detector CD may include an input pad IP, an output pad OP, and a plurality of inverter circuits INV1, INV2, INV3, and INV4. The crack detector CD may receive pulse signals for generating the first test signal TS1 and the second test signal TS2 through the input pad IP and output a first reception signal RS1 or a second reception signal RS2 as a result of the crack detection operation through the output pad OP. In FIG. 5, the crack detector CD is illustrated as including one input pad IP and one output pad OP, but is not limited thereto, and may separately include an input pad and an output pad corresponding to the first crack detection line CL1 and may separately include an input pad and an output pad corresponding to the second crack detection line CL2. In addition, a buffer (or an inverter circuit) may be connected to a front end of the output pad OP to stabilize the waveforms of the first reception signal RS1 and the second reception signal RS2.

The crack detector CD may include first inverter circuits INV1 outputting the first test signal TS1 and second inverter circuits INV2 outputting the second test signal TS2. Each of the first inverter circuits INV1 and the second inverter circuit INV2 is illustrated as including two inverter circuits connected in series, but is not limited thereto and the number of inverter circuits may be adjusted.

The first inverter circuits INV1 may generate the first test signal TS1 according to the first enable signal EN<0> and the inverted first enable signal nEN<0>. The second inverter circuits INV2 may generate the second test signal TS2 according to the second enable signal EN<1> and the inverted second enable signal nEN<1>.

Referring to FIGS. 5 and 6, the first inverter circuit INV1 may include a first P-type transistor P1, a second P-type transistor P2, a first N-type transistor N1, and a second N-type transistor N2 connected in series with each other. Each of the first P-type transistor P1 and the second N-type transistor N2 may be connected to the input terminal IN of the first inverter circuit INV11 to receive an input signal as a gate. The gate of the second P-type transistor P2 may receive the inverted first enable signal nEN<0>, and the gate of the first N-type transistor N1 may receive the first enable signal EN<0>. Accordingly, when the first enable signal EN<0> is a logic high level and the inverted first enable signal nEN<0> is a logic low level, the first inverter circuits INV1 may generate a first test signal TS1 including periodically formed pulses.

Referring back to FIG. 5, the second inverter circuits INV2 having a structure similar to that of the first inverter circuit INV1 may generate the second test signal TS2 according to the second enable signal EN<1> and the inverted second enable signal nEN<1>. For example, when the second enable signal EN<1> is a logic high level and the inverted second enable signal nEN<1> is a logic low level, the second inverter circuits INV2 may generate second test signals TS2 including periodically formed pulses.

The third inverter circuit INV3 may receive the first enable signal EN<0> and generate an inverted first enable signal nEN<0>, and the fourth inverter circuit INV4 may receive the second enable signal EN<1> and generate an inverted second enable signal nEN<1>.

Therefore, the first inverter circuits INV1 and the second inverter circuits INV2 may operate as decoding circuits that select a crack detection line for performing a crack detection operation, and the crack detector CD selects a crack detection line to perform a crack detection operation among the first and second crack detection lines CL1 and CL2 according to the first enable signal EN<0> and the second enable signal EN<1> to generate a first test signal TS1 or a second test signal TS2. That is, when the first enable signal EN<0> is activated (logic high level), the crack detector CD may generate a first test signal TS1 to perform a crack detection operation on the first crack detection line CL1 and when the second enable signal EN<1> is activated (logic high level), the crack detector CD may generate the second test signal TS2 to perform a crack detection operation on the second crack detection line CL2.

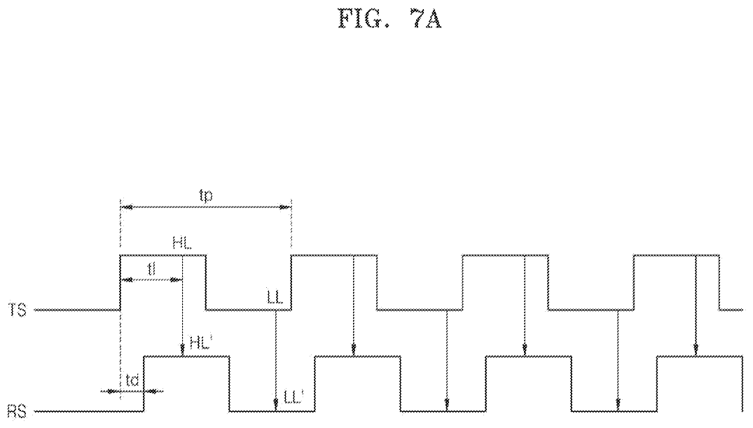

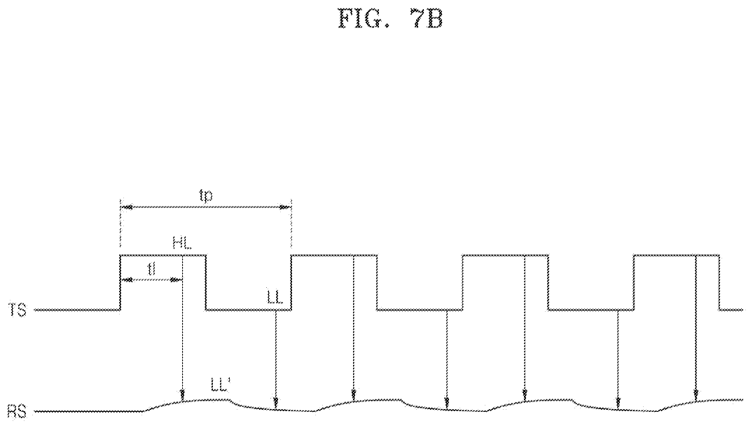

FIG. 7A is a timing diagram for describing a reception signal in a normal state in which no crack is generated in a semiconductor device according to an embodiment. FIG. 7B is a timing diagram for describing a reception signal in a bad state in which a crack occurs in a semiconductor device according to an embodiment.

Referring to FIGS. 5 and 7A, the test signal TS may toggle between a low level LL and a high level HL with a certain period tp. The test signal TS may be one of a first test signal TS1 output through the first crack detection line CL1 and a second test signal TS2 output through the second crack detection line CL2.

The test signal TS may include at least two pulses. Since the test signal TS includes a specified number of pulses instead of one pulse, an error occurring when determining whether a crack has occurred through the waveform of the reception signal RS may be reduced.

The test signal TS may be transmitted through the first crack detection line CL1 or the second crack detection line CL2 and received again by the crack detector CD as a reception signal RS. The reception signal RS may be one of a first reception signal RS1 received from the first crack detection line CL1 to the crack detector CD, and a second reception signal RS2 received from the second crack detection line CL2 to the crack detector CD.

When a crack does not occur in the semiconductor device and is in a normal state, the reception signal RS may be a signal that toggles between a low level LL′ and a high level HL′ with the same cycle tp as the test signal TS. The reception signal RS may be delayed by the delay time td compared to the test signal TS due to parasitic resistance and parasitic capacitance of the first crack detection line CL1 or the second crack detection line CL2.

The crack test circuit of the semiconductor device may determine whether a result of receiving the reception signal RS is the same as the test signal TS within a certain section, and if the results are determined to be the same, it may be determined that the semiconductor device is in a normal state in which no cracks exist. That is, the semiconductor device may measure the period of the reception signal RS and compare the measured period with the period tp of the test signal TS, and if the period tp is the same as the measured period, it may be determined to be in a normal state.

Referring to FIGS. 5 and 7B, when a crack occurs in the semiconductor device, the reception signal RS may maintain a low level LL′. However, unlike that shown in FIG. 7B, the reception signal RS may maintain a high level.

The crack test circuit of the semiconductor device may determine whether a result of receiving the reception signal RS is the same as the test signal TS within a certain section, and for example, the semiconductor device may compare a result of latching the reception signal RS with the test signal TS, and if the result of latching in a certain section is different from the test signal TS, the semiconductor device may determine that a crack exists in the semiconductor device.

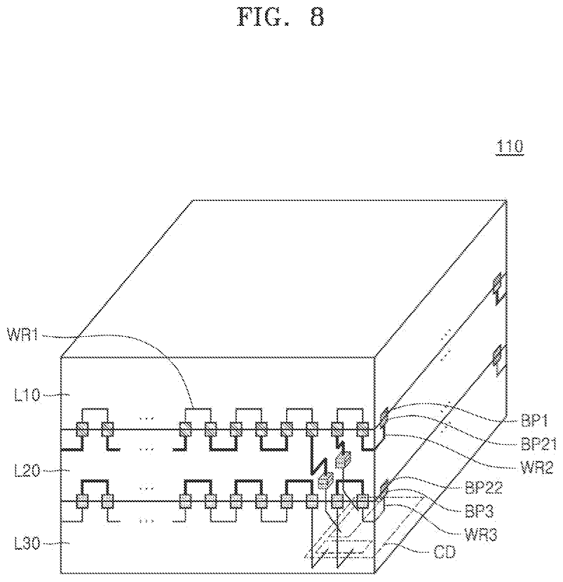

FIG. 8 is a perspective view illustrating a semiconductor device 110 according to an embodiment.

The semiconductor device 110 according to an embodiment may be a memory device. Herein, a memory device may refer to a non-volatile memory device. For example, memory cells included in the semiconductor device 110 may be flash memory cells. Hereinafter, embodiments are described in detail for a case where the memory cells are NAND flash memory cells as an example. However, embodiments of the disclosure are not limited thereto, and in some embodiments, the memory cells may be resistive memory cells such as resistive RAM (ReRAM) memory cells, phase change RAM (PRAM) memory cells, or magnetic RAM (MRAM) memory cells.

Referring to FIG. 8, the semiconductor device 110 may include first, second, and third semiconductor chips L10, L20, and L30, and the first semiconductor chip L10 may be stacked in the vertical direction with respect to the second semiconductor chip L20, and the second semiconductor chip L20 may be stacked in the vertical direction with respect to the third semiconductor chip L30. In this case, the first semiconductor chip L10 and the second semiconductor chip L20 may be semiconductor chips of the same type, and the third semiconductor chip L30 may be a different type of semiconductor chip from the first semiconductor chip L10 and the second semiconductor chip L20. Although FIG. 8 illustrates the semiconductor device 110 in which three semiconductor chips are stacked, embodiments of the disclosure are not limited thereto, and the semiconductor device 110 may further include a semiconductor chip additionally stacked on the first semiconductor chip L10, and in this case, the additionally stacked semiconductor chip may be the same type of semiconductor chip as the first semiconductor chip L10.

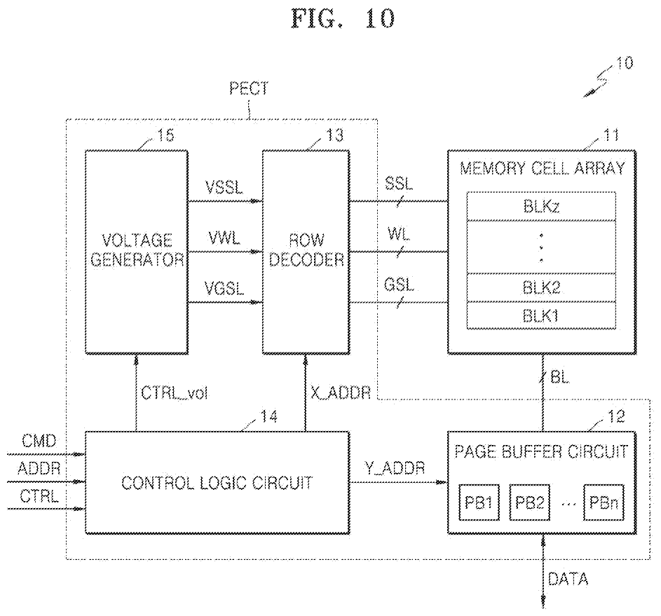

In an embodiment, the memory cell array (e.g., 11 of FIG. 10) may be formed in the first semiconductor chip L10 and the second semiconductor chip L20, and a peripheral circuit (e.g., PECT of FIG. 10) may be formed in the third semiconductor chip L30. Accordingly, the semiconductor device 110 that is a memory device may have a structure in which the memory cell array 11 is disposed on the peripheral circuit PECT, effectively reduce the area in the horizontal direction, and improve the degree of integration of the memory device.

In the first semiconductor chip L10 and the second semiconductor chip L20, metal patterns may be formed for electrically connecting the word lines (e.g., WL of FIG. 10) and the bit lines (e.g., BL of FIG. 10) of the memory cell array 11 to the peripheral circuit PECT formed in the third semiconductor chip L30. The third semiconductor chip L30 may include a substrate, and by forming transistors and metal patterns for wiring the transistors on the substrate, a peripheral circuit PECT may be formed in the third semiconductor chip L30.

In an embodiment, the first semiconductor chip L10 and the second semiconductor chip L20 may be electrically connected to each other through bonding pads BP1 and BP21, and the second semiconductor chip L20 and the third semiconductor chip L30 may be electrically connected to each other through bonding pads BP1, BP21, BP22, and BP3. For example, the bonding pads BP1, BP21, BP22, and BP3 may be formed of copper (Cu), and this bonding method may be a Cu—Cu bonding method. As another example, the bonding pads BP1, BP21, BP22, and BP3 may also be formed of aluminum (Al) or tungsten (W).

The semiconductor device 110 may include a crack detection circuit that detects cracks generated in the first, second, and third semiconductor chips L10, L20, and L30. The crack detection circuit may include a crack detector CD, and a first crack detection line and a second crack detection line electrically connected to the crack detector CD. In an embodiment, the crack detector CD may be disposed at a lower part among the first, second, and third semiconductor chips L10, L20, and L30 and may be formed on the third semiconductor chip L30 on which the peripheral circuit PECT is formed.

The first crack detection line and the second crack detection line may be physically separated from each other and may be connected in parallel. The crack detector CD may transmit a first test signal (e.g., TS1 in FIG. 5) through a first crack detection line, and transmit a second test signal (e.g., TS2 in FIG. 5) to the second crack detection line. Since the crack detector CD may transmit a respective test signal to each of the first crack detection line and the second crack detection line, the semiconductor device 110 may detect a crack detection line in which a crack has occurred from a reception signal received from each of the first crack detection line and the second crack detection line. That is, the semiconductor device 110 may detect a location where a crack is generated among the first, second, and third semiconductor chips L10, L20, and L30.

The first crack detection line may be formed to repeatedly cross the interface between the first semiconductor chip L10 and the second semiconductor chip L20, and the second crack detection line may be formed to repeatedly cross the interface between the second semiconductor chip L20 and the third semiconductor chip L30. For example, the first crack detection line may be formed in a zigzag (or square wave) shape at the interface between the first semiconductor chip L10 and the second semiconductor chip L20 and the second crack detection line may be formed in a zigzag (or square wave) shape at an interface between the second semiconductor chip L20 and the third semiconductor chip L30.

The first crack detection line may be formed to pass through the interface between the first semiconductor chip L10 and the second semiconductor chip L20 and may include a first wiring pattern WR1 and a bonding pad BP1 formed on the first semiconductor chip L10, a bonding pad BP21, a second wiring pattern WR2, and a bonding pad BP22 formed on the second semiconductor chip L20, and a bonding pad BP3 and a third wiring pattern WR3 formed on the third semiconductor chip L30. The first wiring pattern WR1, the bonding pad BP1, the bonding pad BP21, and the second wiring pattern WR2 included in the first crack detection line may form a zigzag pattern.

The second crack detection line may be formed to pass through the interface between the second semiconductor chip L20 and the third semiconductor chip L30 and may include a second wiring pattern WR2 and bonding pad BP22 formed on the second semiconductor chip L20, and a third wiring pattern WR3 and a bonding pad BP3 formed on the third semiconductor chip L30. The second wiring pattern WR2, the bonding pad BP22, the bonding pad BP3, and the third wiring pattern WR3 included in the second crack detection line may form a zigzag pattern.

The bonding pad BP1 of the first semiconductor chip L10 and the bonding pad BP21 of the second semiconductor chip L20 are attached so that the first wiring pattern WR1 and the second wiring pattern WR2 may be electrically connected to each other. The bonding pad BP22 of the second semiconductor chip L20 and the bonding pad BP3 of the third semiconductor chip L30 are attached so that the second wiring pattern WR2 and the third wiring pattern WR3 may be electrically connected to each other.

Each of the first, second, and third wiring patterns WR1, WR2, and WR3 may include a horizontal pattern formed on a certain metal layer of each of the first, second, and third semiconductor chips L10, L20, and L30 and a vertical pattern connecting the horizontal pattern to the bonding pads BP1, BP21, BP22, and BP3.

Each of the first semiconductor chip L10 and the second semiconductor chip L20 may include a cell area (or central area) in which the memory cells of the memory cell array 11 are formed and disposed in the center, and a boundary area formed to surround the cell area. In an embodiment, the first crack detection line and the second crack detection line may be formed in a boundary area. However, embodiments of the disclosure are not limited thereto, and the first crack detection line and the second crack detection line may be formed in the cell area.

The semiconductor device 110 according to one or more embodiments of the disclosure includes a plurality of stacked semiconductor chips L10, L20, and L30, and may include a first crack detection line and a second crack detection line formed to pass through the interface between the plurality of semiconductor chips L10, L20, and L30 to detect cracks generated in the plurality of semiconductor chips L10, L20, and L30 so that it is possible to determine whether a crack has occurred in the semiconductor device 110 and simultaneously detect a location of a semiconductor chip where a crack has occurred.

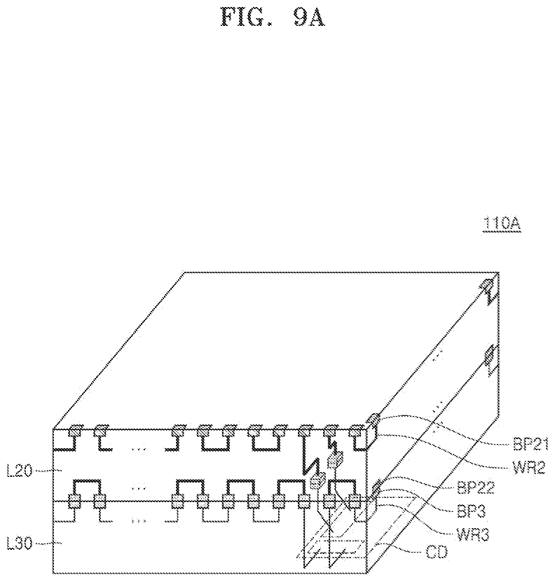

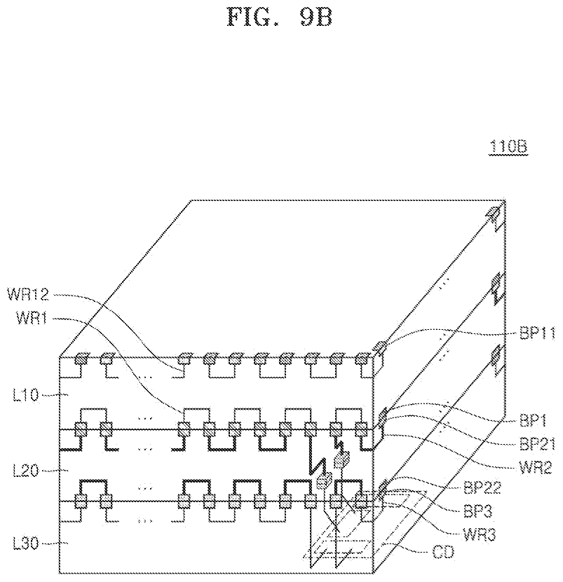

FIGS. 9A and 9B are perspective views illustrating semiconductor devices 110A and 1101B according to an embodiment. In FIGS. 9A and 9B, the same reference numerals as in FIG. 8 will be omitted from overlapping descriptions with respect to FIG. 8.

Referring to FIG. 9A, the semiconductor device 110A may include a plurality of stacked semiconductor chips, for example, a second semiconductor chip L20 and a third semiconductor chip L30. The semiconductor device 110A may be connected to another semiconductor device (e.g., a semiconductor chip on which the memory cell array 11 is formed) attached to the upper portion of the second semiconductor chip L20.

The semiconductor device 110A may include a crack detection circuit that detects cracks generated in the second semiconductor chip L20 and the third semiconductor chip L30. The crack detection circuit may include a crack detector CD, and a first crack detection line and a second crack detection line electrically connected to the crack detector CD.

At this time, the first crack detection line may be formed to contact the upper surface of the second semiconductor chip L20 and may include a second wiring pattern WR2 and bonding pads BP21 and BP22 formed on the second semiconductor chip L20, and a third wiring pattern WR3 and a bonding pad BP3 formed on the third semiconductor chip L30. The first crack detection line may be electrically connected to a wiring pattern (e.g., a pad) of another semiconductor device to be connected to an upper portion of the second semiconductor chip L20. After connecting another semiconductor device to the top of the semiconductor device 110A, the crack detection circuit of the semiconductor device 110A may transmit a test signal through a first crack detection line and receive a reception signal from the first crack detection line, and the semiconductor device 110A may detect a crack generated at an interface between the second semiconductor chip L20 and another semiconductor device.

Referring to FIG. 9B, the semiconductor device 110B may further include a third crack detection line formed to contact the upper surface of the first semiconductor chip L10 compared to the semiconductor device 110 of FIG. 8. That is, the third crack detection line may be formed to be in contact with a surface opposite to the interface between the first semiconductor chip L10 and the second semiconductor chip L20. The third crack detection line may be physically separated from the first crack detection line and the second crack detection line and connected in parallel to each other.

The third crack detection line may include a first wiring pattern WR1 and bonding pads BP11 and BP1 formed on the first semiconductor chip L10, a second wiring pattern WR2 and bonding pads BP21 and BP22 formed on the second semiconductor chip L20, and a third wiring pattern WR3 and a bonding pad BP3 formed on the third semiconductor chip L30. The third crack detection line may be electrically connected to a wiring pattern (e.g., a pad) of another semiconductor device to be connected to an upper portion of the first semiconductor chip L10, and tor example, the first wiring pattern WR1 of the third crack detection line, the bonding pads BP11 and BP1, and wiring patterns of other semiconductor devices may have a zigzag pattern.

After connecting another semiconductor device to the top of the semiconductor device 110B, the crack detection circuit of the semiconductor device 110B may transmit a test signal through a third crack detection line and receive a reception signal from the third crack detection line, and the semiconductor device 110B may detect a crack generated at an interface between the first semiconductor chip L10 and another semiconductor device disposed thereon.

FIG. 10 is a block diagram illustrating a memory device 10 according to an embodiment. For example, the semiconductor devices 110, 110A, and 1101B of FIGS. 8, 9A, and 9B may be the memory device 10 of FIG. 10.

Referring to FIG. 10, the memory device 10 that is a memory device may include a memory cell array 11 and a peripheral circuit PECT, and the peripheral circuit PECT may include a page buffer circuit 12, a row decoder 13, a control logic circuit 14 and a voltage generator 15. The peripheral circuit PECT may further include a data input/output circuit or an input/output interface. In addition, the peripheral circuit PECT may further include a pre-decoder, a temperature sensor, a command decoder, an address decoder, and the like.

The memory cell array 11 may include a plurality of memory blocks BLK1 to BLKz (z is a positive integer), and each of the plurality of memory blocks BLK1 to BLKz may include a plurality of memory cells. The memory cell array 11 may be connected to the page buffer circuit 12 through the bit line BL and may be connected to the row decoder 13 through the word line WL, the string select line SSL, and the ground select line GSL. For example, the memory cells may be flash memory cells. However, embodiments of the disclosure are not limited thereto, and the plurality of memory cells may be resistive memory cells such as resistive RAM (ReRAM) memory cells, phase change RAM (PRAM) memory cells, or magnetic RAM (MRAM) memory cells.

In an embodiment, the memory cell array 11 may include a three-dimensional memory cell array, the three-dimensional memory cell array may include a plurality of NAND strings, and each NAND string may include memory cells respectively connected to word lines vertically stacked on a substrate. U.S. Pat. Nos. 7,679,133, 8,553,466, 8,654,587, 8,559,235, and U.S. Patent Application Publication No. 2011/0233648, the disclosures of which are incorporated therein in their entirety by reference, disclose in detail suitable configurations of a three-dimensional memory array in which a three-dimensional memory array is configured in multiple levels and word lines and/or bit lines are shared between the levels. However, embodiments of the disclosure are not limited thereto, and in some embodiments, the memory cell array 11 may include a two-dimensional memory cell array, and the two-dimensional memory cell array may include a plurality of NAND strings arranged along row and column directions.

The page buffer circuit 12 may include a plurality of page buffers PB1 to PBn (n is a positive integer). Each of the plurality of page buffers PB1 to PBn may be connected to memory cells of the memory cell array 11 through corresponding bit lines. The page buffer circuit 12 may select at least one bit line from among the bit lines BL under the control of the control logic circuit 14. For example, the page buffer circuit 12 may select some of the bit lines BL in response to the column address Y_ADDR received from the control logic circuit 14.

Each of the plurality of page buffers PB1 to PBn may operate as a write driver or a sense amplifier. For example, in a program operation, each of the plurality of page buffers PB1 to PBn may store the data DATA in a memory cell by applying a voltage corresponding to the data DATA to be programmed to a bit line. For example, during a program verify operation or a read operation, each of the plurality of page buffers PB1 to PBn may sense the programmed data DATA by sensing a current or voltage through a bit line.

Based on the command CMD, the address ADDR, and the control signal CTRL, the control logic circuit 14 may output various control signals, for example, the voltage control signal CTRL_vol, the row address X_ADDR, and the column address Y_ADDR, for programming data into the memory cell array 11, reading data from the memory cell array 11, or erasing data stored in the memory cell array 11. Accordingly, the control logic circuit 14 may generally control various operations within the memory device 10. For example, the control logic circuit 14 may receive a command CMD, an address ADDR, and a control signal CTRL from the memory controller.

The voltage generator 15 may generate various types of voltages to perform program, read, and erase operations on the memory cell array 11 based on the voltage control signal CTRL_vol. Specifically, the voltage generator 15 may generate a word line voltage VWL, for example, a program voltage, a read voltage, a pass voltage, an erase verify voltage, or a program verify voltage. Also, the voltage generator 15 may further generate a string select line voltage and a ground select line voltage based on the voltage control signal CTRL_vol.

The row decoder 13 may select one of a plurality of memory blocks BLK1 to BLKz, select one of word lines WL of the selected memory block, and select one of a plurality of string select lines SSL, in response to the row address X_ADDR received from the control logic circuit 14. For example, during a program operation, the row decoder 13 may apply a program voltage and a program verify voltage to a selected word line and during a read operation, the row decoder 13 may apply a read voltage to the selected word line.

According to an embodiment, the memory cell array 11 may be disposed in the first semiconductor chip (e.g., L10 of FIGS. 8 and 9B) and the second semiconductor chip (e.g., L20 of FIGS. 8, 9A and 9B), and the peripheral circuit PECT may be disposed in the third semiconductor chip (e.g., L30 of FIGS. 8, 9A, and 9B).

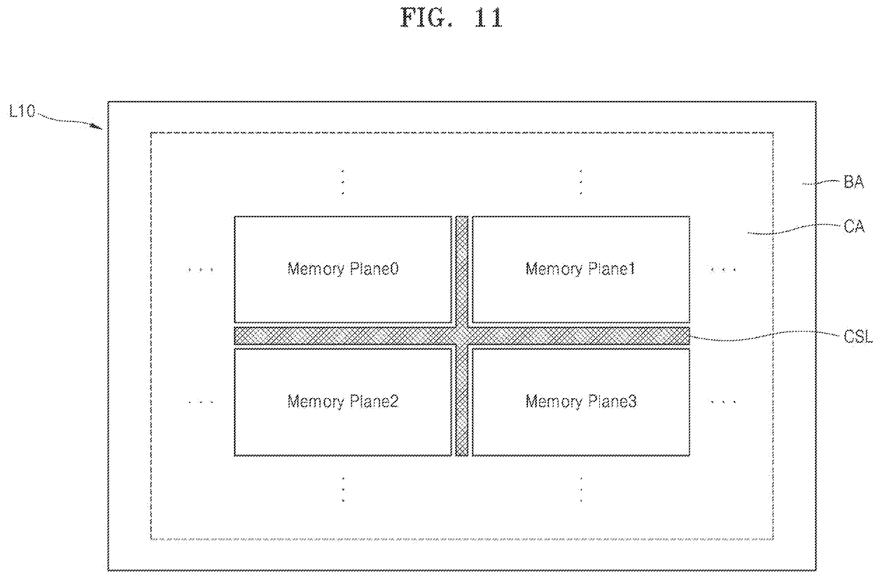

FIG. 11 is a plan view of the first semiconductor chip L10 of the semiconductor device 110 according to an embodiment.

Referring to FIGS. 8 and 11, the first semiconductor chip L10 may include a central area CA, which is a cell area in which a memory cell array is formed, and a boundary area BA formed to surround the central area CA. The first semiconductor chip L10 is described with reference to FIG. 11 as an example, but the second semiconductor chip L20 may also include a central area CA, which is a cell area in which a memory cell array is formed, and a boundary area BA formed to surround the central area CA.

The memory cell array (e.g., 11 of FIG. 10) may be referred to as a memory plane or a MAT. Each of the first semiconductor chip L10 and the second semiconductor chip L20 may include a plurality of memory planes, and page buffers and row decoders may respectively correspond to the different memory planes.

Different memory planes may be physically spaced apart at regular intervals, and a crack detection area CSA in which the first and second crack detection lines are disposed may be formed in the spaced apart space. Accordingly, the first crack detection line and the second crack detection line may be formed in a cross shape in the central area CA when viewing the top surfaces of the first, second, and third semiconductor chips L10, L20, and L30.

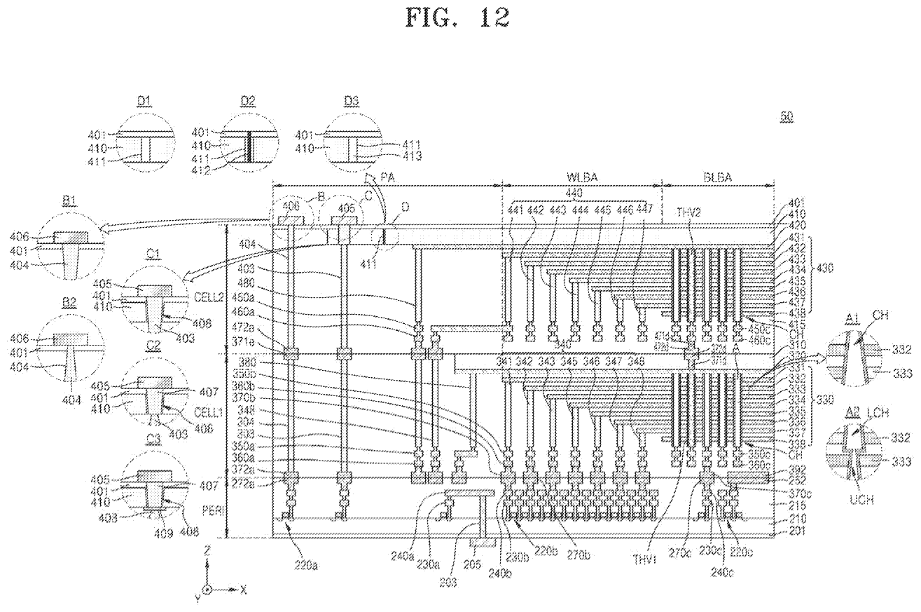

FIG. 12 is a cross-sectional view of a memory device 50 having a bonding vertical NAND (B-VNAND) structure, according to an embodiment. For example, the semiconductor devices 110 and 110B of FIGS. 8 and 9B may be the memory device 50 of FIG. 12.

Referring to FIG. 12, the memory device 50 may have a chip to chip (C2C) structure. Here, the C2C structure may refer to that the at least one upper chip and the lower chip are connected to each other by a bonding method after fabricating at least one upper chip including a cell area CELL and a lower chip including a peripheral circuit area PERI, respectively. For example, the bonding method may refer to a method of electrically or physically connecting the bonding metal pattern formed in the uppermost metal layer of the upper chip to the bonding metal pattern formed in the uppermost metal layer of the lower chip to each other. For example, when the bonding metal patterns are formed of copper (Cu), the bonding method may be a Cu—Cu bonding method. As another example, the bonding metal patterns may also be formed of aluminum (Al) or tungsten (W).

The memory device 50 may include at least one upper chip including a cell area. For example, as shown in FIG. 12, the memory device 50 may be implemented to include two upper chips. However, this is an example, and the number of upper chips is not limited thereto. When the memory device 50 is implemented to include two upper chips, after manufacturing a first upper chip including a first cell area CELL1, a second upper chip including a second cell area CELL2, and a lower chip including a peripheral circuit area PERI, respectively, the memory device 50 may be manufactured by connecting the first upper chip, the second upper chip, and the lower chip to each other using a bonding method. The first upper chip may be reversed and connected to the lower chip by bonding, and the second upper chip may also be reversed and connected to the first upper chip by bonding. In the following description, upper and lower portions of the first and second upper chips are defined based on before the first upper chip and the second upper chip are inverted. That is, in FIG. 12, the upper part of the lower chip refers to the upper part defined based on the +Z-axis direction, and the upper part of each of the first and second upper chips refers to the upper part defined based on the −Z-axis direction. However, this is an example, and only one of the first upper chip and the second upper chip may be inverted and connected by a bonding method.

Each of the peripheral circuit area PERI and the first and second cell areas CELL1 and CELL2 of the memory device 50 may include an outer pad bonding area PA, a word line bonding area WLBA, and a bit line bonding area BLBA. In one embodiment, the memory cell array 11 of FIG. 10 may be formed in the first and second cell areas CELL1 and CELL2, and the peripheral circuit PECT of FIG. 10 may be formed in the peripheral circuit area PERI.

The peripheral circuit area PERI may include a first substrate 210 and a plurality of circuit elements 220a, 220b, and 220c formed on the first substrate 210. An interlayer insulating layer 215 including one or more insulating layers may be provided on the plurality of circuit elements 220a, 220b, and 220c, and a plurality of metal wires connecting the plurality of circuit elements 220a, 220b, and 220c may be provided in the interlayer insulating layer 215. For example, the plurality of metal wires may include first metal wires 230a, 230b, and 230c connected to the plurality of circuit elements 220a, 220b, and 220c, and the second metal wires 240a, 240b, and 240c formed on the first metal wires 230a, 230b, and 230c. The plurality of metal wires may be made of at least one of various conductive materials. For example, the first metal wires 230a, 230b, and 230c may be formed of tungsten having a relatively high electrical resistivity and the second metal wires 240a, 240b, and 240c may be formed of copper having a relatively low electrical resistivity.

In this specification, only the first metal wires 230a, 230b, and 230c and the second metal wires 240a, 240b, and 240c are shown and described, but embodiments of the disclosure are not limited thereto, and at least one metal wire may be further formed on the second metal wires 240a, 240b, and 240c. In this case, the second metal wires 240a, 240b, and 240c may be formed of aluminum. In addition, at least some of the additional metal wires formed on the second metal wires 240a, 240b, and 240c may be formed of copper having a lower electrical resistivity than aluminum of the second metal wires 240a, 240b, and 240c.

The interlayer insulating layer 215 is disposed on the first substrate 210 and may include an insulating material, such as silicon oxide or silicon nitride.

Each of the first and second cell areas CELL1 and CELL2 may include at least one memory block. The first cell area CELL1 may include the second substrate 310 and the common source line 320. A plurality of word lines 331 to 338 (i.e., 330) may be stacked on the second substrate 310 in a direction (Z-axis direction) perpendicular to the upper surface of the second substrate 310. String select lines and a ground select line may be disposed above and below the word lines 330, and a plurality of word lines 330 may be disposed between the string select lines and the ground select line. Similarly, the second cell area CELL2 includes the third substrate 410 and the common source line 420, and a plurality of word lines 431 to 438 (i.e., 430) may be stacked along a direction perpendicular to the upper surface of the third substrate 410 (Z-axis direction). The second substrate 310 and the third substrate 410 may be made of various materials and for example, may include a silicon substrate, a silicon-germanium substrate, a germanium substrate, or a substrate having a monocrystalline epitaxial layer grown on a monocrystalline silicon substrate. A plurality of channel structures CH may be formed in each of the first and second cell areas CELL1 and CELL2.

In an embodiment, as shown in A1, the channel structure CH is provided in the bit line bonding area BLBA and extends in a direction perpendicular to the upper surface of the second substrate 310 to pass through the word lines 330, the string select lines, and the ground select line. The channel structure CH may include a data storage layer, a channel layer, and a buried insulating layer. The channel layer may be electrically connected to the first metal wire 350c and the second metal wire 360c in the bit line bonding area BLBA. For example, the second metal wire 360c may be a bit line and may be connected to the channel structure CH through the first metal wire 350c. The bit line 360c may extend in a first direction (Y-axis direction) parallel to the upper surface of the second substrate 310.

In an embodiment, as shown in A2, the channel structure CH may include a lower channel LCH and an upper channel UCH connected to each other. For example, the channel structure CH may be formed through a process for the lower channel LCH and a process for the upper channel UCH. The lower channel LCH may extend in a direction perpendicular to the top surface of the second substrate 310 and pass through the common source line 320 and the lower word lines 331 and 332. The lower channel LCH may include a data storage layer, a channel layer, and a buried insulating layer and may be connected to the upper channel UCH. The upper channel UCH may pass through the upper word lines 333 to 338. The upper channel UCH may include a data storage layer, a channel layer, a buried insulating layer, and the like, and the channel layer of the upper channel UCH may be electrically connected to the first metal wire 350c and the second metal wire 360c. As the length of the channel increases, it may be difficult to form a channel having a constant width due to process reasons. The memory device 50 according to an embodiment may include a channel having improved width uniformity through the lower channel LCH and the upper channel UCH formed through a sequential process.

As shown in A2, when the channel structure CH includes the lower channel LCH and the upper channel UCH, a word line positioned near a boundary between the lower channel LCH and the upper channel UCH may be a dummy word line. For example, word lines 332 and 333 forming boundaries between the lower channel LCH and the upper channel UCH may be dummy word lines. In this case, data may not be stored in memory cells connected to the dummy word line. Alternatively, the number of pages corresponding to memory cells connected to a dummy word line may be less than the number of pages corresponding to memory cells connected to a general word line. The voltage level applied to the dummy word line may be different from the voltage level applied to the general word line, and accordingly, the influence of the non-uniform channel width between the lower channel LCH and the upper channel UCH on the operation of the memory device may be reduced.

In A2, it is shown that the number of lower word lines 331 and 332 through which the lower channel LCH passes is less than the number of upper word lines 333 to 338 through which the upper channel UCH passes. However, this is merely an example, and embodiments of the disclosure are not limited thereto. As another example, the number of lower word lines passing through the lower channel LCH may be equal to or greater than the number of upper word lines passing through the upper channel UCH. In addition, the above-described structure and connection relationship of the channel structure CH disposed in the first cell area CELL1 may be equally applied to the channel structure CH disposed in the second cell area CELL2.

In the bit line bonding area BLBA, the first through electrode THV1 may be provided in the first cell area CELL1, and the second through electrode THV2 may be provided in the second cell area CELL2. The first through electrode THV1 may pass through the common source line 320 and the plurality of word lines 330. However, this is an example, and the first through electrode THV1 may further penetrate the second substrate 310. The first through electrode THV1 may include a conductive material. Alternatively, the first through electrode THV1 may include a conductive material surrounded by an insulating material. The second through electrode THV2 may also be provided in the same shape and structure as the first through electrode THV1.

In an embodiment, the first through electrode THV1 and the second through electrode THV2 may be electrically connected to each other through the first through metal pattern 372d and the second through metal pattern 472d. The first through metal pattern 372d may be formed on the lower end of the first upper chip including the first cell area CELL1, and the second through metal pattern 472d may be formed on the upper end of the second upper chip including the second cell area CELL2. The first through electrode THV1 may be electrically connected to the first metal wire 350c and the second metal wire 360c. A lower via 371d may be formed between the first through electrode THV1 and the first through metal pattern 372d, and an upper via 471d may be formed between the second through electrode THV2 and the second through metal pattern 472d. The first through metal pattern 372d and the second through metal pattern 472d may be connected by a bonding method.

Also, in the bit line bonding area BLBA, an upper metal pattern 252 may be formed on the uppermost metal layer of the peripheral circuit area PERI, and an upper metal pattern 392 having the same shape as the upper metal pattern 252 may be formed on the uppermost metal layer of the first cell area CELL1. The upper metal pattern 392 of the first cell area CELL1 and the upper metal pattern 252 of the peripheral circuit area PERI may be electrically connected to each other by a bonding method. In the bit line bonding area BLBA, the bit line 360c may be electrically connected to a page buffer included in the peripheral circuit area PERI. For example, some of the circuit elements 220c of the peripheral circuit area PERI may provide a page buffer, and the bit line 360c may be electrically connected to circuit elements 220c providing a page buffer through the upper bonding metal 370c of the first cell area CELL1 and the upper bonding metal 270c of the peripheral circuit area PERI.

Continuing to refer to FIG. 12, in the word line bonding area WLBA, the word lines 330 of the first cell area CELL1 may extend along a second direction (X-axis direction) parallel to the upper surface of the second substrate 310 and may be connected to the plurality of cell contact plugs 341 to 347 (i.e., 1340). A first metal layer 350b and a second metal layer 360b may be sequentially connected to the upper portions of the cell contact plugs 340 connected to the word lines 330. The cell contact plugs 340 may be connected to the peripheral circuit area PERI in the word line bonding area WLBA through the upper bonding metal 370b of the first cell area CELL1 and the upper bonding metal 270b of the peripheral circuit area PERI.

The cell contact plugs 340 may be electrically connected to a row decoder included in a peripheral circuit area PERI. For example, some of the circuit elements 220b of the peripheral circuit area PERI provide a row decoder, and the cell contact plugs 340 may be electrically connected to circuit elements 220b providing row decoders through the upper bonding metal 370b of the first cell area CELL1 and the upper bonding metal 270b of the peripheral circuit area PERI. In an embodiment, the operating voltage of the circuit elements 220b providing the row decoder may be different from the operating voltage of the circuit elements 220c providing the page buffer. For example, operating voltages of circuit elements 220c providing a page buffer may be higher than operating voltages of circuit elements 220b providing a row decoder.

Similarly, in the word line bonding area WLBA, the word lines 430 of the second cell area CELL2 may extend along a second direction (X-axis direction) parallel to the upper surface of the third substrate 410, and may be connected to the plurality of cell contact plugs 441 to 447 (i.e., 440). The cell contact plugs 440 may be connected to a peripheral circuit area PERI through the upper metal pattern of the second cell area CELL2, the lower and upper metal patterns of the first cell area CELL1, and the cell contact plug 348.

In the word line bonding area WLBA, an upper bonding metal 370b may be formed in the first cell area CELL1, and an upper bonding metal 270b may be formed in the peripheral circuit area PERI. The upper bonding metal 370b of the first cell area CELL1 and the upper bonding metal 270b of the peripheral circuit area PERI may be electrically connected to each other by a bonding method. The upper bonding metal 370b and the upper bonding metal 270b may be formed of aluminum, copper, or tungsten.

In the outer pad bonding area PA, a lower metal pattern 371e may be formed below the first cell area CELL1, and an upper metal pattern 472a may be formed above the second cell area CELL2. The lower metal pattern 371e of the first cell area CELL1 and the upper metal pattern 472a of the second cell area CELL2 may be connected to each other in the outer pad bonding area PA by a bonding method. Similarly, an upper metal pattern 372a may be formed above the first cell area CELL1, and an upper metal pattern 272a may be formed above the peripheral circuit area PERI. The upper metal pattern 372a of the first cell area CELL1 and the upper metal pattern 272a of the peripheral circuit area PERI may be connected to each other by a bonding method.

Common source line contact plugs 380 and 480 may be disposed in the outer pad bonding area PA. The common source line contact plugs 380 and 480 may be formed of a conductive material, such as metal, metal compound, or doped polysilicon. The common source line contact plug 380 of the first cell area CELL1 may be electrically connected to the common source line 320, and the common source line contact plug 480 of the second cell area CELL2 may be electrically connected to the common source line 420. A first metal wire 350a and a second metal wire 360a are sequentially stacked on the upper portion of the common source line contact plug 380 of the first cell area CELL1, and a first metal wire 450a and a second metal wire 460a may be sequentially stacked on the common source line contact plug 480 of the second cell area CELL2.

Input/output pads 205, 405, and 406 may be disposed in the outer pad bonding area PA. Referring to FIG. 12, a lower insulating film 201 may cover a lower surface of the first substrate 210 and a first input/output pad 205 may be formed on the lower insulating film 201. The first input/output pad 205 may be connected to at least one of a plurality of circuit elements 220a disposed in a peripheral circuit area PERI through a first input/output contact plug 203, and may be separated from the first substrate 210 by the lower insulating film 201. In addition, a side insulating film may be disposed between the first input/output contact plug 203 and the first substrate 210 to electrically separate the first input/output contact plug 203 from the first substrate 210.

An upper insulating film 401 covering an upper surface of the third substrate 410 may be formed on the third substrate 410. A second input/output pad 405 and/or a third input/output pad 406 may be disposed on the upper insulating film 401. The second input/output pad 405 may be connected to at least one of a plurality of circuit elements 220a disposed in a peripheral circuit area PERI through the second input/output contact plugs 403 and 303, and the third input/output pad 406 may be connected to at least one of the plurality of circuit elements 220a disposed in the peripheral circuit area PERI through the third input/output contact plugs 404 and 304.

In an embodiment, the third substrate 410 may not be disposed in an area where the input/output contact plugs are disposed. For example, as shown in B, the third input/output contact plug 404 is separated from the third substrate 410 in a direction parallel to the upper surface of the third substrate 410, and may pass through the interlayer insulating layer 415 of the second cell area CELL2 and be connected to the third input/output pad 406. In this case, the third input/output contact plug 404 may be formed through various processes.

For example, as shown in B1, the third input/output contact plug 404 may extend in a third direction (Z-axis direction) and may have a larger diameter toward the upper insulating film 401. That is, while the diameter of the channel structure CH described in A1 is formed to decrease toward the upper insulating film 401, a diameter of the third input/output contact plug 404 may be formed to increase toward the upper insulating film 401. For example, the third input/output contact plug 404 may be formed after the second cell area CELL2 and the first cell area CELL1 are coupled by a bonding method.

Also, as shown in B2, the third input/output contact plug 404 extends in the third direction (Z-axis direction) and may be formed to have a smaller diameter toward the upper insulating film 401. That is, the diameter of the third input/output contact plug 404 may be formed to decrease toward the upper insulating film 401 like the channel structure CH. For example, the third input/output contact plug 404 may be formed together with the cell contact plugs 440 before the second cell area CELL2 and the first cell area CELL1 are bonded together.

In another embodiment, the input/output contact plugs may be disposed to overlap the third substrate 410. For example, as shown in C, the second input/output contact plug 403 is formed by penetrating the interlayer insulating layer 415 of the second cell area CELL2 in the third direction (Z-axis direction), and may be electrically connected to the second input/output pad 405 through the third substrate 410. In this case, the connection structure between the second input/output contact plug 403 and the second input/output pad 405 may be implemented in various ways.

As shown in C1, an opening 408 penetrating the third substrate 410 is formed, and the second input/output contact plug 403 may be directly connected to the second input/output pad 405 through the opening 408 formed in the third substrate 410. In this case, as shown in C1, the diameter of the second input/output contact plug 403 may increase toward the second input/output pad 405. However, this is an example, and the diameter of the second input/output contact plug 403 may be formed to decrease toward the second input/output pad 405.

For example, as shown in C2, an opening 408 penetrating the third substrate 410 may be formed, and a contact 407 may be formed in the opening 408. One end of the contact 407 may be connected to the second input/output pad 405 and the other end may be connected to the second input/output contact plug 403. Accordingly, the second input/output contact plug 403 may be electrically connected to the second input/output pad 405 through the contact 407 in the opening 408. In this case, as shown in C2, the diameter of the contact 407 may be formed to increase toward the second input/output pad 405, and the diameter of the second input/output contact plug 403 may be formed to decrease toward the second input/output pad 405. For example, the third input/output contact plug 403 may be formed together with the cell contact plugs 440 before the second cell area CELL2 and the first cell area CELL1 are bonded together, and the contact 407 may be formed after bonding the second cell area CELL2 and the first cell area CELL1.

Also, as shown in C3, a stopper 409 may be further formed on the upper surface of the opening 408 of the third substrate 410 compared to C2. The stopper 409 may be a metal wire formed on the same layer as the common source line 420. However, this is an example, and the stopper 409 may be a metal wire formed on the same layer as at least one of the word lines 430. The second input/output contact plug 403 may be electrically connected to the second input/output pad 405 through the contact 407 and the stopper 409.

Similar to the second and third input/output contact plugs 403 and 404 of the second cell area CELL2, the diameters of the second and third input/output contact plugs 303 and 304 of the first cell area CELL1 may be formed to decrease toward the lower metal pattern 371e, or may be formed to increase toward the lower metal pattern 371e.

According to embodiments, a slit 411 may be formed in the third substrate 410. For example, the slit 411 may be formed at an arbitrary position of the outer pad bonding area PA. For example, as shown in D, the slit 411 may be located between the second input/output pad 405 and the cell contact plugs 440 when viewed from a plan view. However, this is example, and the slit 411 may be formed such that the second input/output pad 405 is positioned between the slit 411 and the cell contact plugs 440 when viewed from a plan view.

As shown in D1, the slit 411 may be formed to pass through the third substrate 410. The slit 411 may be used, for example, to prevent the third substrate 410 from being finely cracked when the opening 408 is formed. However, this is example, and the slit 411 may be formed to a depth of about 60 to about 70% of the thickness of the third substrate 410.

Also, as an example, as shown in D2, a conductive material 412 may be formed in the slit 411. The conductive material 412 may be used, for example, to discharge leakage current generated during driving of circuit elements in an outer pad bonding area PA to the outside. In this case, the conductive material 412 may be connected to an external ground line.

Also, as an example, as shown in D3, an insulating material 413 may be formed in the slit 411. The insulating material 413, for example, may be formed to electrically separate the second input/output pad 405 and the second input/output contact plug 403 disposed in the outer pad bonding area PA from the word line bonding area WLBA. By forming an insulating material 413 in the slit 411, it is possible to block the voltage provided through the second input/output pad 405 from affecting the metal layer disposed on the third substrate 410 in the word line bonding area WLBA.

According to embodiments, the first, second, and third input/output pads 205, 405, and 406 may be selectively formed. For example, the memory device 50 may be implemented to include only the first input/output pad 205 disposed on the first substrate 210, or include only the second input/output pad 405 disposed on the third substrate 410, or include only the third input/output pad 406 disposed on the upper insulating film 401.

According to one or more embodiments, at least one of the second substrate 310 of the first cell area CELL1 and the third substrate 410 of the second cell area CELL2 may be used as a sacrificial substrate, and may be completely or partially removed before or after the bonding process. Additional films may be deposited after substrate removal. For example, the second substrate 310 of the first cell area CELL1 may be removed before or after bonding of the peripheral circuit area PERI and the first cell area CELL1, and an insulating film covering an upper surface of the common source line 320 or a conductive film for connection may be formed. Similarly, the third substrate 410 of the second cell area CELL2 may be removed before or after bonding of the first cell area CELL1 and the second cell area CELL2, and an upper insulating film 401 covering an upper surface of the common source line 420 or a conductive film for connection may be formed.

Referring to FIGS. 8 and 10, the memory device 50 may include a crack detection circuit, and the crack detection circuit may include a crack detector CD, a first crack detection line formed to pass through the interface between the first cell area CELL1 and the second cell area CELL2 in a zigzag pattern, and a second crack detection line formed to pass through an interface between the second cell area CELL2 and the peripheral circuit area PERI in a zigzag pattern. In an embodiment, the first crack detection line and the second crack detection line may be formed in the outer pad bonding area PA.

While embodiments of the disclosure have been particularly shown and described, it will be understood that various changes in form and details may be made therein without departing from the spirit and scope of the following claims.

What is claimed is:

1. A semiconductor device comprising:
a first semiconductor chip;
a second semiconductor chip stacked on the first semiconductor chip, wherein a type of the second semiconductor chip is different from a type of the first semiconductor chip; and
a crack detection circuit comprising:
a first crack detection line repeatedly passing through an interface between the first semiconductor chip and the second semiconductor chip;
a second crack detection line comprising a bonding pad or a through-via structure contacting a surface of the second semiconductor chip opposite to the interface; and
a crack detector in the second semiconductor chip, the crack detector being configured to:
output a first test signal to the first crack detection line,
receive a first reception signal from the first crack detection line,
output a second test signal to the second crack detection line, and
receive a second reception signal from the second crack detection line.

2. The semiconductor device of claim 1, wherein the first crack detection line and the second crack detection line are physically separated from each other, and
wherein each of first crack detection line and the second crack detection line have a zigzag pattern.

3. The semiconductor device of claim 1, wherein the second semiconductor chip is provided under the first semiconductor chip,
wherein the semiconductor device further comprises a third semiconductor chip provided under the second semiconductor chip,
wherein the second crack detection line further comprises a wiring pattern in the second semiconductor chip, and a wiring pattern in the third semiconductor chip, and
wherein the second crack detection line repeatedly passes through an interface between the second semiconductor chip and the third semiconductor chip.

4. The semiconductor device of claim 1, wherein the second semiconductor chip is provided on top of the first semiconductor chip,
wherein the semiconductor device further comprises a third semiconductor chip provided on top of the second semiconductor chip,
wherein the second crack detection line comprises the through-via structure, a wiring pattern in the second semiconductor chip, and a wiring pattern in the third semiconductor chip, and
wherein the second crack detection line repeatedly passes through an interface between the second semiconductor chip and the third semiconductor chip.

5. The semiconductor device of claim 1, wherein an area of the first semiconductor chip in a horizontal direction is less than an area of the second semiconductor chip in the horizontal direction.

6. The semiconductor device of claim 1, wherein the first semiconductor chip comprises a central area in which semiconductor elements are formed and a boundary area around the central area, and
wherein the first crack detection line is provided in the boundary area.

7. The semiconductor device of claim 1, wherein the crack detector comprises:
a plurality of first inverter circuits configured to transmit the first test signal to the first crack detection line in response to a first enable signal; and
a plurality of second inverter circuits configured to transmit the second test signal to the second crack detection line in response to a second enable signal.

8. The semiconductor device of claim 1, wherein the first crack detection line comprises a first wiring pattern, a first bonding pad on the first semiconductor chip, a second wiring pattern, and a second bonding pad on the second semiconductor chip,
wherein the first wiring pattern comprises a horizontal pattern on a metal layer of the first semiconductor chip and a vertical pattern connecting the horizontal pattern to the first bonding pad, and
wherein the second wiring pattern comprises a horizontal pattern on a metal layer of the second semiconductor chip and a vertical pattern connecting the horizontal pattern to the second bonding pad.

9. A semiconductor device comprising:
a first semiconductor chip including a memory cell array;
a second semiconductor chip provided under the first semiconductor chip and comprising a peripheral circuit; and
a crack detection circuit comprising:
a first crack detection line repeatedly passing through an interface between the first semiconductor chip and the second semiconductor chip;
a second crack detection line comprising a bonding pad contacting a surface of the first semiconductor chip opposite to the interface; and
a crack detector in the second semiconductor chip, the crack detector being configured to:
output a first test signal to the first crack detection line,
receive a first reception signal from the first crack detection line,
output a second test signal to the second crack detection line, and
receive a second reception signal from the second crack detection line.

10. The semiconductor device of claim 9, wherein the first crack detection line and the second crack detection line are physically separated from each other, and
wherein each of first crack detection line and the second crack detection line have a zigzag pattern.

11. The semiconductor device of claim 9, further comprising a third semiconductor chip on top of the first semiconductor chip and comprising a memory array,
wherein the second crack detection line further comprises a wiring pattern in the first semiconductor chip, a wiring pattern in the third semiconductor chip, and a bonding pad of the third semiconductor chip, and
wherein the second crack detection line repeatedly passes through an interface between the first semiconductor chip and the third semiconductor chip.

12. The semiconductor device of claim 11, wherein the crack detection circuit further comprises a third crack detection line comprising a bonding pad contacting a surface of the third semiconductor chip opposite to an interface of the first semiconductor chip and the second semiconductor chip, and
wherein the third crack detection line is physically separated from the first crack detection line and the second crack detection line.

13. The semiconductor device of claim 12, wherein the crack detector is further configured to output a third test signal to the third crack detection line and receive a third reception signal from the third crack detection line.

14. The semiconductor device of claim 9, wherein the first semiconductor chip comprises a central area in which the memory cell array is provided and a boundary area around the central area, and
wherein the first crack detection line is in the boundary area.

15. The semiconductor device of claim 9, wherein the first semiconductor chip comprises a plurality of memory planes,
wherein the first semiconductor chip comprises a central area in which the plurality of memory planes are provided and a boundary area around the central area, and
wherein the first crack detection line is in a space in which different memory planes among the plurality of memory planes are spaced apart from each other in the central area.

16. The semiconductor device of claim 9, wherein the crack detector comprises:
a plurality of first inverter circuits configured to transmit the first test signal to the first crack detection line in response to a first enable signal; and
a plurality of second inverter circuits configured to transmit the second test signal to the second crack detection line in response to a second enable signal.

17. A semiconductor device comprising:
a first semiconductor chip;
a second semiconductor chip, each of the first semiconductor chip and the second semiconductor chip comprises a memory cell array;
a third semiconductor chip stacked under the second semiconductor chip and comprising a peripheral circuit; and
a crack detection circuit comprising:
a first crack detection line that repeatedly passes through an interface between the first semiconductor chip and the second semiconductor chip;
a second crack detection line that repeatedly passes through an interface between the second semiconductor chip and the third semiconductor chip; and
a crack detector in the third semiconductor chip, the crack detector being configured to:
output a first test signal to the first crack detection line,
receive a first reception signal from the first crack detection line,
output a second test signal to the second crack detection line, and
receive a second reception signal from the second crack detection line.

18. The semiconductor device of claim 17, wherein each of the first semiconductor chip and the second semiconductor chip further comprises a central area in which the memory cell array is disposed and a boundary area around the central area, and
wherein the first crack detection line and the second crack detection line are in the boundary area of the first semiconductor chip and the boundary area of the second semiconductor chip.

19. The semiconductor device of claim 17, wherein each of the first semiconductor chip and the second semiconductor chip further comprises a plurality of memory planes,
wherein each of the first semiconductor chip and the second semiconductor chip comprises a central area in which the plurality of memory planes are disposed and a boundary area around the central area, and
wherein each of the first crack detection line and the second crack detection line is in a space in which different memory planes among the plurality of memory planes are spaced apart from each other in the central area of the first semiconductor chip and the central area of the second semiconductor chip.

20. The semiconductor device of claim 17, wherein the first crack detection line and the second crack detection line are physically separated from each other.
